(19) United States
(12) Patent Application Publication
(10) Pub. No.: US 2016/0343994 A1
(43) Pub. Date: Nov. 24, 2016

(54) KNOCKDOWN MASK AND MANUFACTURING METHOD THEREOF

(71) Applicant: SHENZHEN CHINA STAR OPTOELECTRONICS TECHNOLOGY CO. LTD., Guangdong (CN)

(72) Inventors: Tsungyuan WU, Shenzhen, Guangdong (CN); Yawei LIU, Shenzhen, Guangdong (CN)

(73) Assignee: Shenzhen China Star Optoelectronics Technology Co. Ltd., Shenzhen, Guangdong (CN)

(21) Appl. No.: 14/429,777

(22) PCT Filed: Feb. 9, 2015
(86) PCT No.: PCT/CN2015/072597

§ 371 Date: Mar. 19, 2015

(30) Foreign Application Priority Data
Dec. 31, 2014 (CN) 201410851833.9

(51) Int. Cl. H01L 51/56

(52) U.S. Cl. CPC H01L 51/56

(57) ABSTRACT

The present invention provides a knockdown mask and a manufacturing method thereof. The knockdown mask includes a mask frame (1), a plurality of first shielding plates (2), and a plurality of second shielding plates (3). The plurality of first shielding plates (2) and the plurality of second shielding plates (3) intersect each other to form a grid like structure that includes a plurality of film forming holes (4). Thicknesses of the plurality of first shielding plates (2) and the plurality of second shielding plates (3) are identical. The first shielding plates (2) each have first troughs (21) formed therein to extend completely through the width of the first shielding plate (2) at intersections thereof with the second shielding plates (3). The second shielding plates (3) each have second troughs (31) formed therein to extend completely through the width of the second shielding plate (3) at intersections thereof with the first shielding plates (2). The first and second shielding plates (2, 3) are inter-fit to and intersect each other through the first and second troughs (21, 31) in such a way that upper and lower surfaces of the first and second shielding plates (2, 3) are respectively one the same planes.

### BACKGROUND OF THE INVENTION

1. Field of the Invention

The present invention relates to the field of manufacture of OLED (Organic Light Emitting Diode), and in particular to a knockdown mask and a manufacturing method thereof.

2. The Related Arts

OLED (Organic Light Emitting Diode) is a flat panel displaying technique of extremely prosperous future and it shows excellent displaying performance and also possesses various advantages, such as being self-luminous, simple structure, being ultra-thin, fast response, wide view angle, low power consumption, and being capable of achieving flexible displaying and is thus regarded as a “dream display”. In addition, the investment of manufacturing installation is far less than that of TFT-LCDs (Thin-Film Transistor Liquid Crystal Displays) so that it is now favored by major display manufacturers and becomes the mainstream of the third-generation display devices in the field of displaying technology. Being on the eve of mass production, new techniques of OLED emerges virtually unlimitedly with the deepening of research and development thereof and thus, OLED displays are undergoing a break-through progress.

An OLED comprises an anode, an organic light emission layer, and a cathode that are formed, in sequence, on a substrate. Each functional material layer of the OLED and the film of the cathode metal layer are generally formed through the vacuum thermal evaporation technology. The vacuum thermal evaporation technology involves the use of a mask. The purpose of the mask is to have the OLED material vapor-deposited on a desired location. Thus, the locations and shapes of openings and surface regularity of the mask are of vital importance. FIG. 1 is a schematic view illustrating a vacuum thermal evaporation process of an OLED material. A crucible 100 receives and holds therein an OLED material 200 that is to be evaporated. In an environment of vacuum less than 10⁻⁵Pa, the temperature of the crucible 100 is gradually raised and when the vaporization temperature of the OLED material 200 is reached, the OLED material 200 gradually changes into gaseous state and gets sublimated and flowing upward to move through the openings of a mask 300. The gaseous molecules deposits down on a surface of a substrate 400 and cools down to solidified into solid state molecules. The molecules of the OLED material are continuously deposited to gradually form a thin film on the substrate 400.

Referring to FIGS. 2-6, schematic views are given to illustrate a manufacturing process of a conventional small-sized mask for vacuum thermal evaporation of an OLED material. The manufacturing process generally comprises: step 1, in which, as shown in FIG. 2, a stainless steel mask frame 10 is formed; step 2, in which, as shown in FIG. 3, a mask base plate 20′ is provided, wherein the mask base plate 20′ is generally a thin stainless steel or nickel-iron alloy steel sheet of 20 micrometers to 100 micrometers; step 3, in which, as shown in FIG. 4, the mask base plate 20′ is subjected to a patternization treatment, wherein small openings 21 are formed in the mask base plate 20′ to form a mask 20; step 4, in which, as shown in FIG. 5, a force is applied to a circumference of the mask 20 to flatten the surface thereof with the openings 21 not distorted, followed by alignment of the mask 20 with the mask frame 10; and step 5, in which, as shown in FIG. 6, laser spot welding is applied to joint the mask 20 with the mask frame 10. After the above-described process of manufacturing, the mask 20 has a flat and regular surface and the openings 21 are not distorted. Further, the mask 20 can be readily usable through moving of the mask frame 10.

For high generation manufacturing lines of white OLED (WOLED), particularly the sixth generation or higher, the mask used is constructed in such a way that the size of the mask base plate is greater than 1500 mm×1800 mm. There is generally no single flat sheet of raw material plate of such a size available for being hollowed to form a mask. And, thus, a knockdown mask must be employed.

In a known large-sized knockdown mask for used in a high generation manufacturing line of WOLED, overlapped areas have different thicknesses, it often needs to make slots in the mask frame in order to prevent breaking of substrate in a lamination operation and there is also shadowing effect induced.

### SUMMARY OF THE INVENTION

An object of the present invention is to provide a knockdown mask, which comprises a mask frame that requires not slotting and that makes the thickness of a mask portion consistent so as to reduce the difficult of machining for surface polishing in repairing the mask frame and to allow for easy reuse of the mask frame and to prevent the occurrence of shadowing effect.

An object of the present invention is also to provide a mask manufacturing method, which is applicable to manufacturing a large-sized knockdown mask, wherein by adopting such a method to make a knockdown mask, the mask frame requires no slotting and the thickness of the mask portion is consistent so as to reduce the difficult of machining for surface polishing in repairing the mask frame and to allow for easy reuse of the mask frame and to prevent the occurrence of shadowing effect.

To achieve the above objects, the present invention first provides a knockdown mask, which comprises a mask frame, a plurality of first shielding plates arranged side by side and parallel to long edges of the mask frame, and a plurality of second shielding plates arranged side by side and parallel to short edges of the mask frame;

the plurality of first shielding plates each having two ends respectively fixed through spot welding to the short edges of the mask frame, the plurality of second shielding plates each having two ends respectively fixed through spot welding to the long edges of the mask frame; the plurality of first shielding plates and the plurality of second shielding plates intersecting each other so as to form a grid like structure that comprises a plurality of film forming holes;

thicknesses of the plurality of first shielding plates and the plurality of second shielding plates being identical; the first shielding plates each comprising first troughs formed therein to extend completely through a width of the first shielding plate at intersections thereof with the second shielding plates, the second shielding plates each comprising second troughs formed therein to extend completely through a width of the second shielding plate at intersections thereof with the first shielding plates; the first and second shielding plates being inter-fit to and intersecting each other through the first and second troughs in such a way that upper and lower surfaces of the first and second shielding plates are respectively on the same planes.

A dimension of the first troughs measured in a length direction of the first shielding plate is equal to the width of the second shielding plate and a dimension of the second troughs measured in a length direction of the second shielding plate is equal to the width of the first shielding plate.

A sum of depths of the first and second troughs is equal to the thickness of the first shielding plates or the second shielding plates.

The depths of the first and second troughs are equal to one half of the thickness of the first shielding plates or the second shielding plates.

Portions of the first and second shielding plates that are inter-fit to and intersect each other through the first and second troughs are subjected to laser welding to have the first shielding plates and the second shielding plates securely fixed together.

The present invention also provides a manufacturing method of a knockdown mask, which comprises the following steps:

(1) forming a plurality of first shielding plates and a plurality of second shielding plates through etching or laser manufacturing;

wherein thicknesses of the plurality of first shielding plates and the plurality of second shielding plates are identical; the first shielding plates each comprise first troughs formed therein to extend completely through the width of the first shielding plate at intersections thereof with the second shielding plates and the second shielding plates each comprise second troughs formed therein to extend completely through the width of the second shielding plate at intersections thereof with the first shielding plates;

(2) providing a mask frame and fixing two ends of each of the plurality of first shielding plates through spot welding to short edges of the mask frame and fixing two ends of each of the plurality of second shielding plates through spot welding to long edges of the mask frame;

wherein the plurality of first shielding plates and the plurality of second shielding plates intersect each other so as to form a grid like structure that comprises a plurality of film forming holes; the first and second shielding plates are inter-fit to and intersect each other through the first and second troughs in such a way that upper and lower surfaces of the first and second shielding plates are respectively on the same planes; and

(3) applying laser welding to portions of the first and second shielding plates that are inter-fit to and intersect each other through the first and second troughs so as to have the first shielding plates and the second shielding plates securely fixed to each other.

Step (2) is performed by first having the plurality of first shielding plates and the plurality of second shielding plates intersecting each other and two ends of each of the plurality of first and second shielding plates fixed through spot welding to the mask frame.

Step (2) is alternatively performed by first having two ends of each of the plurality of first shielding plates or two ends of each of the second shielding plates fixed through spot welding to the mask frame and then having two ends of each of the second shielding plates or two ends of each of the first shielding plates fixed through spot welding to the mask frame.

A dimension of the first troughs measured in a length direction of the first shielding plate is equal to the width of the second shielding plate and a dimension of the second troughs measured in a length direction of the second shielding plate is equal to the width of the first shielding plate; and a sum of depths of the first and second troughs is equal to the thickness of the first shielding plates or the second shielding plates.

The depths of the first and second troughs are equal to one half of the thickness of the first shielding plates or the second shielding plates.

The present invention further provides a knockdown mask, which comprises a mask frame, a plurality of first shielding plates arranged side by side and parallel to long edges of the mask frame, and a plurality of second shielding plates arranged side by side and parallel to short edges of the mask frame;

the plurality of first shielding plates each having two ends respectively fixed through spot welding to the short edges of the mask frame, the plurality of second shielding plates each having two ends respectively fixed through spot welding to the long edges of the mask frame; the plurality of first shielding plates and the plurality of second shielding plates intersecting each other so as to form a grid like structure that comprises a plurality of film forming holes;

thicknesses of the plurality of first shielding plates and the plurality of second shielding plates being identical; the first shielding plates each comprising first troughs formed therein to extend completely through a width of the first shielding plate at intersections thereof with the second shielding plates, the second shielding plates each comprising second troughs formed therein to extend completely through a width of the second shielding plate at intersections thereof with the first shielding plates; the first and second shielding plates being inter-fit to and intersecting each other through the first and second troughs in such a way that upper and lower surfaces of the first and second shielding plates are respectively on the same planes;

wherein a dimension of the first troughs measured in a length direction of the first shielding plate is equal to the width of the second shielding plate and a dimension of the second troughs measured in a length direction of the second shielding plate is equal to the width of the first shielding plate; and

wherein a sum of depths of the first and second troughs is equal to the thickness of the first shielding plates or the second shielding plates.

The efficacy of the present invention is that the present invention provides a knockdown mask and a manufacture method thereof, in which a mask frame is assembled with first and second shielding plates with the first and second shielding plates being of the same thickness and the first and second shielding plates being inter-fit to and intersecting each other through first and second troughs so as to have upper and lower surfaces of the first and second shielding plates respectively on the same planes. The total thickness of an intersection site between the first and second shielding plates is identical to the thickness of an individual first or second shielding plate so that the mask frame requires no slotting and the thickness of the mask portion is consistent to thereby reduce the difficulty of machining for flatness in a polishing operation for repairing of the mask frame and allow for easy reuse of the mask frame and thus eliminating the occurrence of shadow effect that is found in the conventional large-sized knockdown mask.

For better understanding of the features and technical contents of the present invention, reference is had to a detailed description of the present invention given below, together with the attached drawings. The drawings, however, are provided for illustration and description only and are not intended to impose undue limitations to the scope of the present invention.

### BRIEF DESCRIPTION OF THE DRAWINGS

The technical solution, as well as other beneficial advantages, of the present invention will become apparent from the following detailed description of an embodiment of the present invention, with reference to the attached drawings.

In the drawings:

FIG. 1 is a schematic view illustrating a vacuum thermal evaporation process of an OLED material;

FIG. 2 is a schematic view illustrating step 1 of a conventional mask manufacturing method;

FIG. 3 is a schematic view illustrating step 2 of the conventional mask manufacturing method;

FIG. 4 is a schematic view illustrating step 3 of the conventional mask manufacturing method;

FIG. 5 is a schematic view illustrating step 4 of the conventional mask manufacturing method;

FIG. 6 is a schematic view illustrating step 5 of the conventional mask manufacturing method;

FIG. 7 is a top plan view showing a knockdown mask according to the present invention;

FIG. 8 is a schematic view illustrating first and second shielding plates of the knockdown mask of the present invention intersecting each other to form a grid-like structure;

FIG. 9 is a cross-sectional view taken along line C-C of FIG. 8;

FIG. 10 is a cross-sectional view taken along line D-D of FIG. 8;

FIG. 11 is a perspective view of the first shielding plate of the knockdown mask according to the present invention;

FIG. 12 is a perspective view of the second shielding plate of the knockdown mask according to the present invention;

FIG. 13 is a flow chart illustrating a manufacturing method of the knockdown mask according to the present invention;

FIGS. 14A and 14B are schematic views illustrating step 2 of the manufacturing method of the knockdown mask according to a first embodiment example of the present invention; and

FIGS. 15A and 15B are schematic views illustrating step 2 of the manufacturing method of the knockdown mask according to a second embodiment example of the present invention.

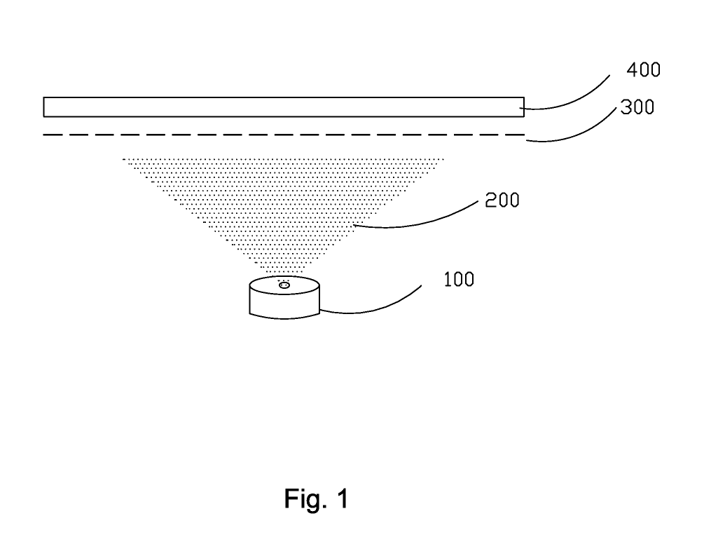

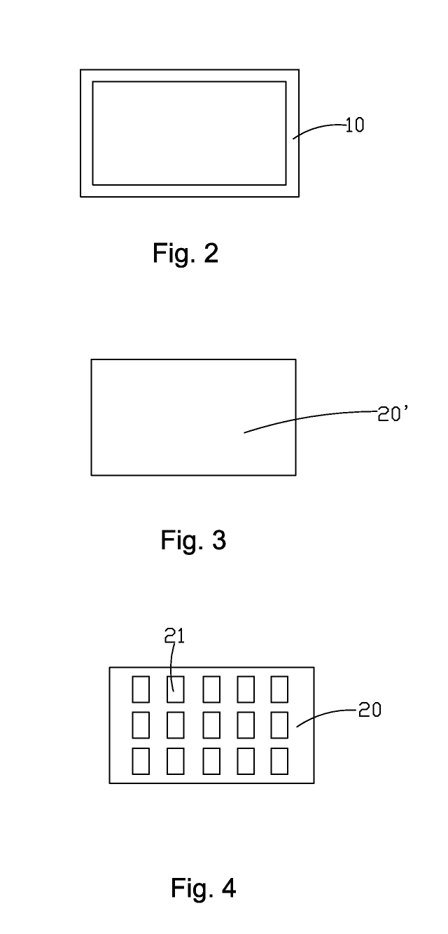

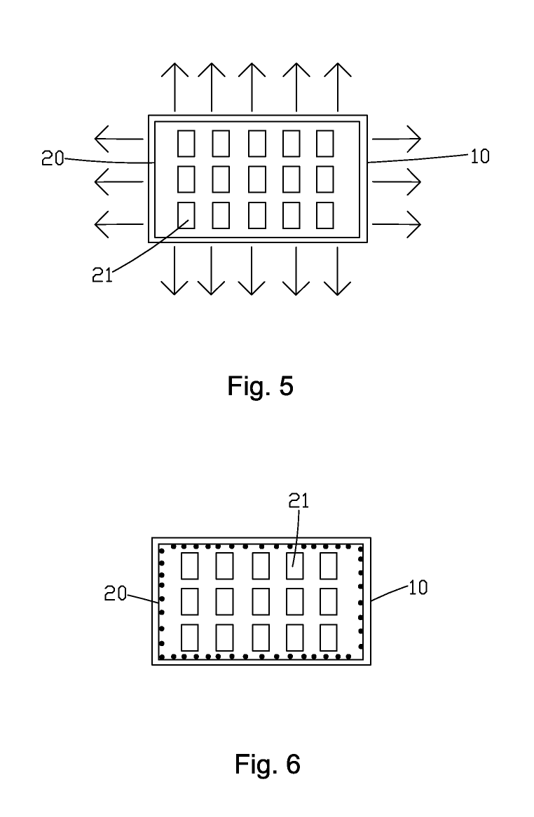

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

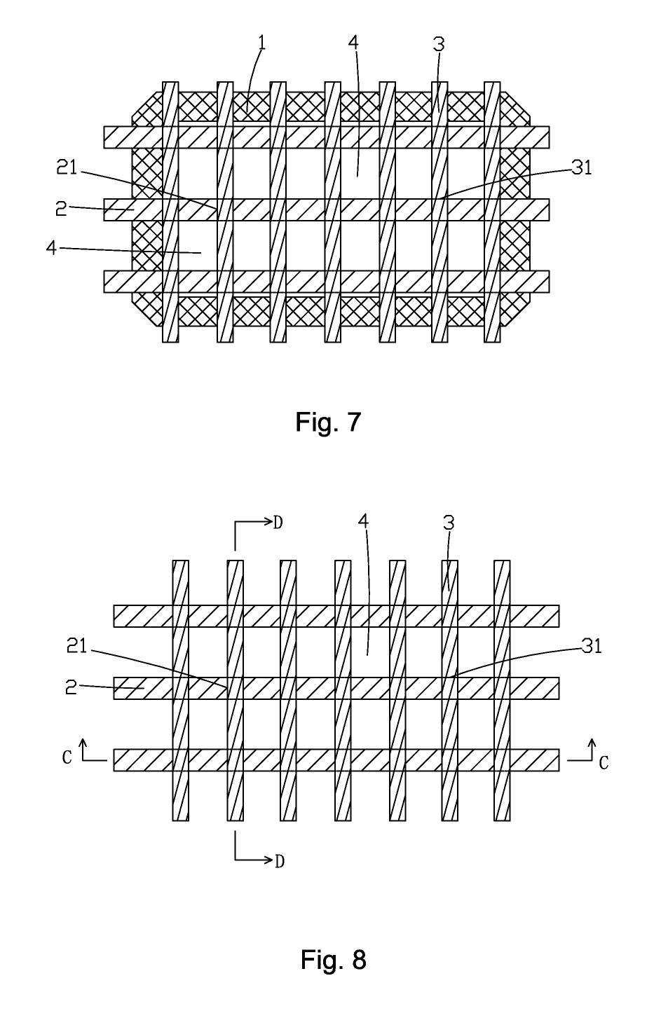

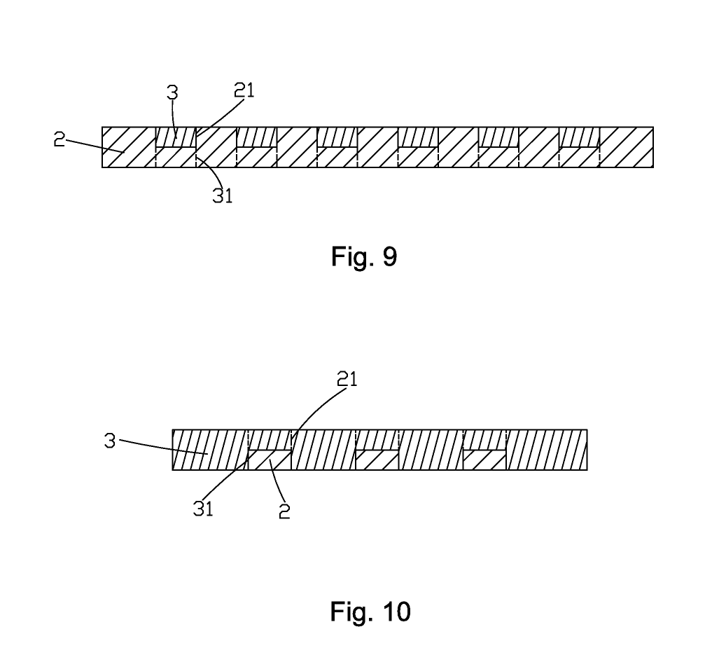

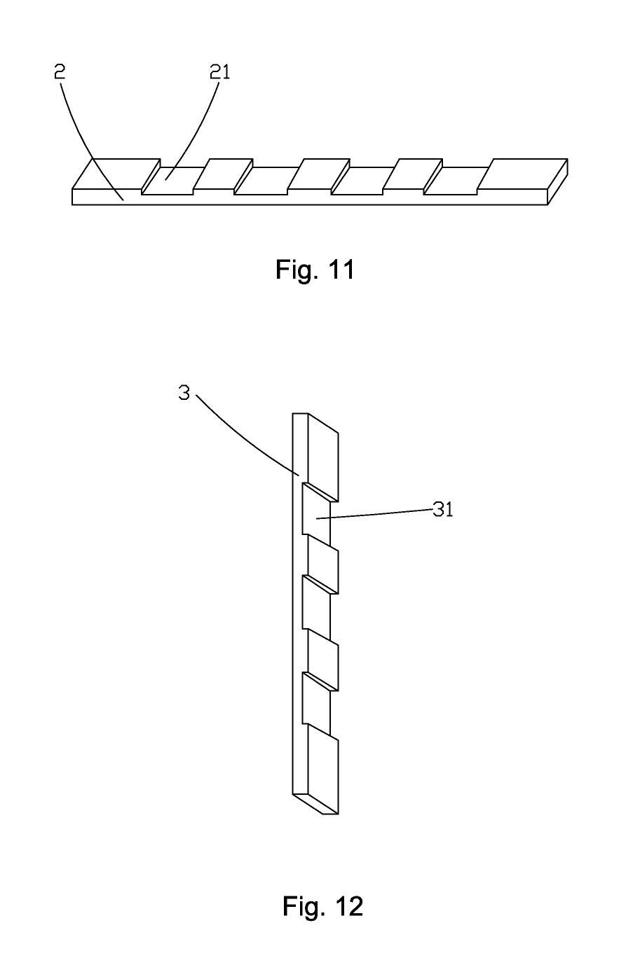

Referring collectively to FIGS. 7-12, the present invention first provides a knockdown mask, which comprises:

a mask frame 1, wherein the mask frame 1 comprises four edges, the four edges circumferentially delimit an open area;

a plurality of first shielding plates 2, wherein the plurality of first shielding plates 2 are arranged side by side and parallel to long edges of the mask frame 1; and

a plurality of second shielding plates 3, wherein the plurality of second shielding plates 3 are arranged side by side and parallel to short edges of the mask frame 1.

The plurality of first shielding plates 2 each has two ends that are respectively fixed, through spot welding, to the short edges of the mask frame 1. The plurality of second shielding plates 3 each has two ends that are respectively fixed, through spot welding, to the long edges of the mask frame 1. The plurality of first shielding plates 2 and the plurality of second shielding plates 3 intersect each other so as to form a grid like structure that comprises a plurality of film forming holes 4. The grid like structure constitutes a mask pattern.

It is noted here that thicknesses of the plurality of first shielding plates 2 and the plurality of second shielding plates 3 are identical. The first shielding plates 2 each comprise first troughs 21 formed therein to extend completely through the width of the first shielding plate 2 at intersections thereof with the second shielding plates 3. The second shielding plates 3 each comprise second troughs 31 formed therein to extend completely through the width of the second shielding plate 3 at intersections thereof with the first shielding plates 2. The first and second shielding plates 2, 3 inter-fit and intersect each other through the first and second troughs 21, 31 in such a way that upper and lower surfaces of the first and second shielding plates 2, 3 are respectively on the same planes and the total thickness at the intersection sites of the first and second shielding plates 2, 3 is identical to the thickness of each individual first or second shielding plate 2, 3, whereby the thickness of the mask portion is made consistent. Such an arrangement requires no slot or recess formed in the mask frame 1 and thus reduces the difficult of machining for flatness in a polishing operation for repairing of the mask frame 1 and allows for easy reuse of the mask frame 1, and on the other hand, the technical issue of shadow effect caused by thickness difference of an overlapping or intersecting site of a mask portion of a conventional large-sized knockdown mask can be overcome.

Specifically, a dimension of the first trough 21 measured in a length direction of the first shielding plate 2 is equal to the width of the second shielding plate 3 and a dimension of the second trough 31 measured in a length direction of the second shielding plate 3 is equal to the width of the first shielding plate 2, whereby the first and second shielding plates 2, 3 are securely inter-fit to each other through the first and second troughs 21, 31.

A sum of depths of the first and second troughs 21, 31 is equal to the thickness of the first shielding plate 2 or the second shielding plate 3. Preferably, the depths of the first and second troughs 21, 31 are both one half (½) of the thickness of the first shielding plate 2 or the second shielding plate 3 so that when the first and second shielding plates 2, 3 are inter-fit to and intersect each other through the first and second troughs 21, 31, the upper surfaces of the first and second shielding plates 2, 3 are on the same plane and the lower surfaces of the first and second shielding plates 2, 3 are on the same plane.

Further, the portions of the first and second shielding plates 2, 3 that are inter-fit to and intersecting each other through the first and second troughs 21, 31 are then subjected to laser welding so as to have the first shielding plates 2 and the second shielding plates 3 securely fixed to each other.

The knockdown mask is applicable to vapor deposition of an OLED organic material or an inorganic material such as lithium fluoride (LiF) and is also applicable to other fields of vacuum thermal evaporation and is also applicable to other processes of film formation, such as screen printing, laser trans-printing, and spraying coating film formation.

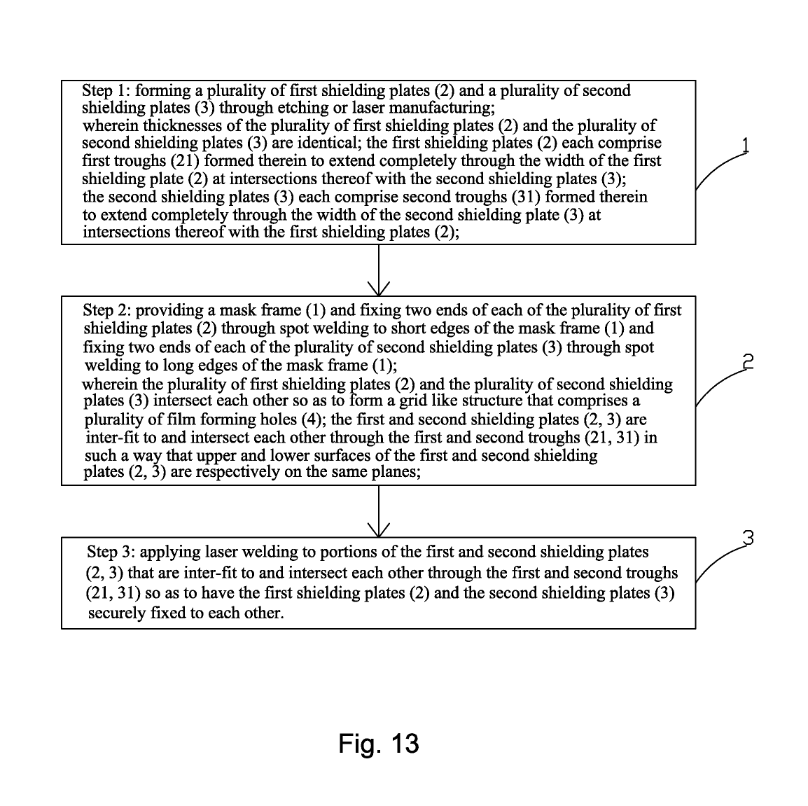

Referring to FIG. 13, in combination with FIGS. 7-12, the present invention also provides a manufacturing method of a knockdown mask, which comprises the following steps:

Step 1: forming a plurality of first shielding plates 2 and a plurality of second shielding plates 3 through etching or laser manufacturing.

Thicknesses of the plurality of first shielding plates 2 and the plurality of second shielding plates 3 are identical. The first shielding plates 2 each comprise first troughs 21 formed therein to extend completely through the width of the first shielding plate 2 at intersections thereof with the second shielding plates 3. The second shielding plates 3 each comprise second troughs 31 formed therein to extend completely through the width of the second shielding plate 3 at intersections thereof with the first shielding plates 2.

Specifically, a dimension of the first trough 21 measured in a length direction of the first shielding plate 2 is equal to the width of the second shielding plate 3 and a dimension of the second trough 31 measured in a length direction of the second shielding plate 3 is equal to the width of the first shielding plate 2. A sum of depths of the first and second troughs 21, 31 is equal to the thickness of the first shielding plate 2 or the second shielding plate 3. Preferably, the depths of the first and second troughs 21, 31 are both one half (½) of the thickness of the first shielding plate 2 or the second shielding plate 3.

Step 2: providing a mask frame 1 and fixing two ends of each of the plurality of first shielding plates 2 through spot welding to short edges of the mask frame 1 and fixing two ends of each of the plurality of second shielding plates 3 through spot welding to long edges of the mask frame 1.

The plurality of first shielding plates 2 and the plurality of second shielding plates 3 intersect each other so as to form a grid like structure that comprises a plurality of film forming holes 4. The grid like structure constitutes a mask pattern. The first and second shielding plates 2, 3 are inter-fit to and intersect each other through the first and second troughs 21, 31 in such a way that upper and lower surfaces of the first and second shielding plates 2, 3 are respectively on the same planes.

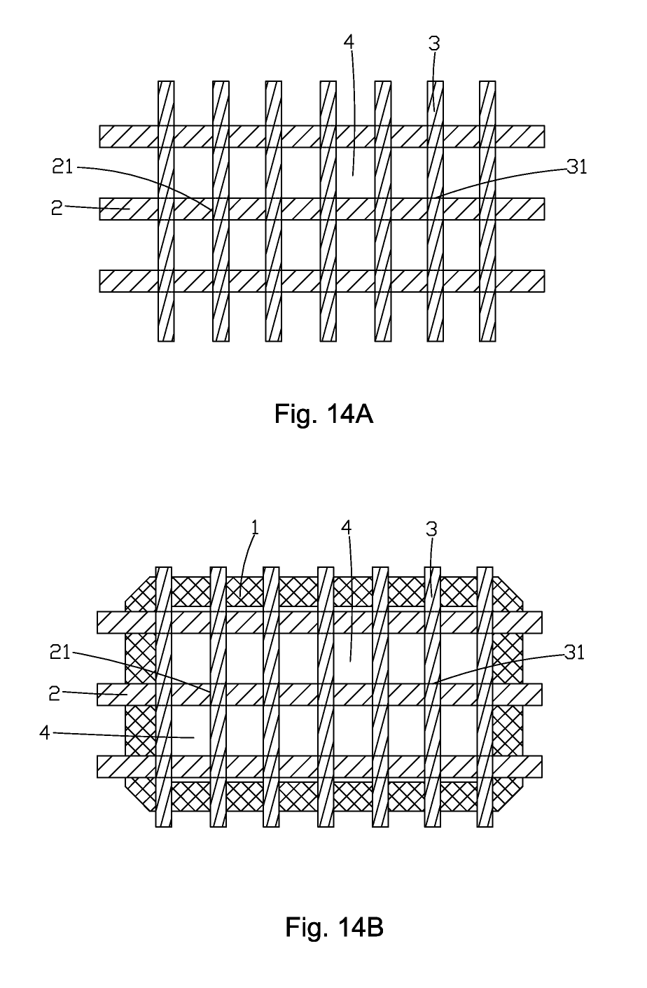

Step 2 can be performed in two ways. As shown in FIGS. 14A and 14B, Step 2 is performed by first having the plurality of first shielding plates 2 and the plurality of second shielding plates 3 intersecting each other to form a grid like structure and then having two ends of each of the plurality of first and second shielding plates 2, 3 fixed to the mask frame 1 through spot welding.

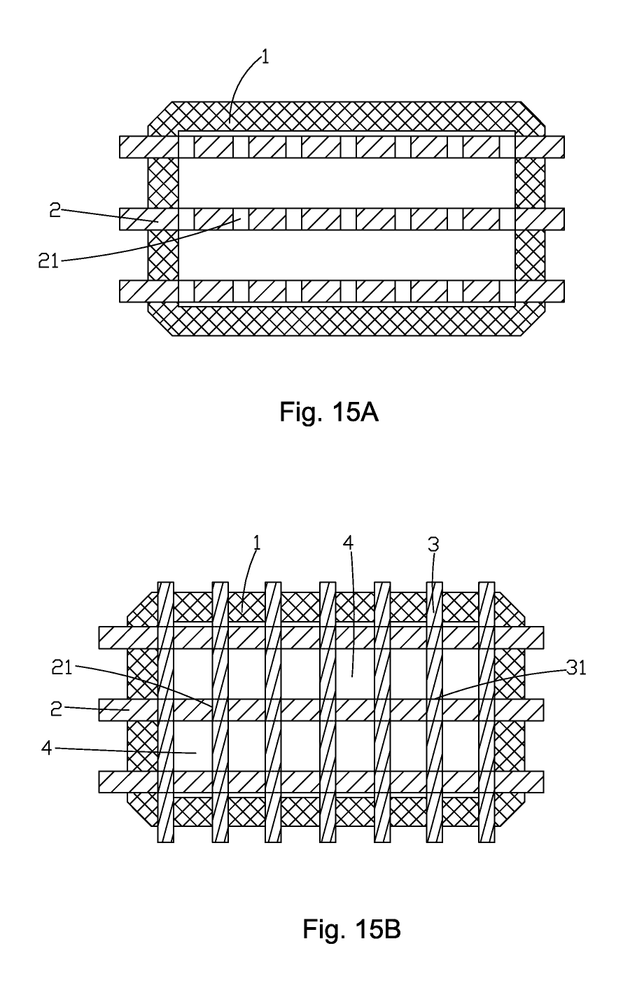

As shown in FIGS. 15A and 15B, Step 2 may be alternatively performed by first having two ends of each of the plurality of first shielding plates 2 fixed to the mask frame 1 through spot welding, and then having two ends of each of the second shielding plates 3 fixed to the mask frame 1 through spot welding so as to form a grid like structure. Apparently, in this way of performance, the two ends of each of the plurality of second shielding plates 3 may be first fixed to the mask frame 1 through spot welding and then the two ends of each of the first shielding plates 2 are fixed to the mask frame 1 through spot welding so as to form the grid like structure.

Step 3: applying laser welding to portions of the first and second shielding plates 2, 3 that are inter-fit to and intersect each other through the first and second troughs 21, 31 so as to have the first shielding plates 2 and the second shielding plates 3 securely fixed to each other.

To this point, the manufacture of the knockdown mask is completed.

For a knockdown mask manufactured through the above method, there is no need to form a slot or recess in the mask frame 1 and the thickness of the mask portion is consistent so as to reduce the difficulty of machining for flatness in a polishing operation for repairing of the mask frame 1 and allows for easy reuse of the mask frame 1 and thus eliminating the occurrence of shadow effect that is found in the conventional large-sized knockdown mask.

In summary, the present invention provides a knockdown mask and a manufacture method thereof, in which a mask frame is assembled with first and second shielding plates with the first and second shielding plates being of the same thickness and the first and second shielding plates being inter-fit to and intersecting each other through first and second troughs so as to have upper and lower surfaces of the first and second shielding plates respectively on the same planes. The total thickness of an intersection site between the first and second shielding plates is identical to the thickness of an individual first or second shielding plate so that the mask frame requires no slotting and the thickness of the mask portion is consistent to thereby reduce the difficulty of machining for flatness in a polishing operation for repairing of the mask frame and allow for easy reuse of the mask frame and thus eliminating the occurrence of shadow effect that is found in the conventional large-sized knockdown mask.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A knockdown mask, comprising a mask frame, a plurality of first shielding plates arranged side by side and parallel to long edges of the mask frame, and a plurality of second shielding plates arranged side by side and parallel to short edges of the mask frame;
the plurality of first shielding plates each having two ends respectively fixed through spot welding to the short edges of the mask frame, the plurality of second shielding plates each having two ends respectively fixed through spot welding to the long edges of the mask frame; the plurality of first shielding plates and the plurality of second shielding plates intersecting each other so as to form a grid like structure that comprises a plurality of film forming holes;
thicknesses of the plurality of first shielding plates and the plurality of second shielding plates being identical; the first shielding plates each comprising first troughs formed therein to extend completely through a width of the first shielding plate at intersections thereof with the second shielding plates, the second shielding plates each comprising second troughs formed therein to extend completely through a width of the second shielding plate at intersections thereof with the first shielding plates; the first and second shielding plates being inter-fit to and intersecting each other through the first and second troughs in such a way that upper and lower surfaces of the first and second shielding plates are respectively on the same planes.

2. The knockdown mask as claimed in claim 1, wherein a dimension of the first troughs measured in a length direction of the first shielding plate is equal to the width of the second shielding plate and a dimension of the second troughs measured in a length direction of the second shielding plate is equal to the width of the first shielding plate.

3. The knockdown mask as claimed in claim 1, wherein a sum of depths of the first and second troughs is equal to the thickness of the first shielding plates or the second shielding plates.

4. The knockdown mask as claimed in claim 3, wherein the depths of the first and second troughs are equal to one half of the thickness of the first shielding plates or the second shielding plates.

5. The knockdown mask as claimed in claim 1, wherein portions of the first and second shielding plates that are inter-fit to and intersect each other through the first and second troughs are subjected to laser welding to have the first shielding plates and the second shielding plates securely fixed together.

6. A manufacturing method of a knockdown mask, comprising the following steps:
(1) forming a plurality of first shielding plates and a plurality of second shielding plates through etching or laser manufacturing;
wherein thicknesses of the plurality of first shielding plates and the plurality of second shielding plates are identical; the first shielding plates each comprise first troughs formed therein to extend completely through the width of the first shielding plate at intersections thereof with the second shielding plates and the second shielding plates each comprise second troughs formed therein to extend completely through the width of the second shielding plate at intersections thereof with the first shielding plates;
(2) providing a mask frame and fixing two ends of each of the plurality of first shielding plates through spot welding to short edges of the mask frame and fixing two ends of each of the plurality of second shielding plates through spot welding to long edges of the mask frame;
wherein the plurality of first shielding plates and the plurality of second shielding plates intersect each other so as to form a grid like structure that comprises a plurality of film forming holes; the first and second shielding plates are inter-fit to and intersect each other through the first and second troughs in such a way that upper and lower surfaces of the first and second shielding plates are respectively on the same planes; and
(3) applying laser welding to portions of the first and second shielding plates that are inter-fit to and intersect each other through the first and second troughs so as to have the first shielding plates and the second shielding plates securely fixed to each other.

7. The manufacturing method of the knockdown mask as claimed in claim 6, wherein step (2) is performed by first having the plurality of first shielding plates and the plurality of second shielding plates intersecting each other and two ends of each of the plurality of first and second shielding plates fixed through spot welding to the mask frame.

8. The manufacturing method of the knockdown mask as claimed in claim 6, wherein step (2) is performed by first having two ends of each of the plurality of first shielding plates or two ends of each of the second shielding plates fixed through spot welding to the mask frame and then having two ends of each of the second shielding plates or two ends of each of the first shielding plates fixed through spot welding to the mask frame.

9. The manufacturing method of the knockdown mask as claimed in claim 6, wherein a dimension of the first troughs measured in a length direction of the first shielding plate is equal to the width of the second shielding plate and a dimension of the second troughs measured in a length direction of the second shielding plate is equal to the width of the first shielding plate; and a sum of depths of the first and second troughs is equal to the thickness of the first shielding plates or the second shielding plates.

10. The manufacturing method of the knockdown mask as claimed in claim 9, wherein the depths of the first and second troughs are equal to one half of the thickness of the first shielding plates or the second shielding plates.

11. A knockdown mask, comprising a mask frame, a plurality of first shielding plates arranged side by side and parallel to long edges of the mask frame, and a plurality of second shielding plates arranged side by side and parallel to short edges of the mask frame;
the plurality of first shielding plates each having two ends respectively fixed through spot welding to the short edges of the mask frame, the plurality of second shielding plates each having two ends respectively fixed through spot welding to the long edges of the mask frame; the plurality of first shielding plates and the plurality of second shielding plates intersecting each other so as to form a grid like structure that comprises a plurality of film forming holes;
thicknesses of the plurality of first shielding plates and the plurality of second shielding plates being identical; the first shielding plates each comprising first troughs formed therein to extend completely through a width of the first shielding plate at intersections thereof with the second shielding plates, the second shielding plates each comprising second troughs formed therein to extend completely through a width of the second shielding plate at intersections thereof with the first shielding plates; the first and second shielding plates being inter-fit to and intersecting each other through the first and second troughs in such a way that upper and lower surfaces of the first and second shielding plates are respectively on the same planes;
wherein a dimension of the first troughs measured in a length direction of the first shielding plate is equal to the width of the second shielding plate and a dimension of the second troughs measured in a length direction of the second shielding plate is equal to the width of the first shielding plate; and
wherein a sum of depths of the first and second troughs is equal to the thickness of the first shielding plates or the second shielding plates.

12. The knockdown mask as claimed in claim 11, wherein the depths of the first and second troughs are equal to one half of the thickness of the first shielding plates or the second shielding plates.

13. The knockdown mask as claimed in claim 11, wherein portions of the first and second shielding plates that are inter-fit to and intersect each other through the first and second troughs are subjected to laser welding to have the first shielding plates and the second shielding plates securely fixed together.
